(19) United States
(12) Patent Application Publication
(10) Pub. No.: US 2007/0144773 A1
(43) Pub. Date: Jun. 28, 2007

(54) Circuit board

(75) Inventors: Akiyoshi Saitou, Kawasaki (JP); Toru Kuraishi, Kawasaki (JP); Takeshi Midorikawa, Kawasaki (JP); Chikayuki Kumagai, Kawasaki (JP); Masashi Fujimoto, Kawasaki (JP)

Correspondence Address: ARMSTRONG, KRATZ, QUINTOS, HANSON & BROOKS, LLP, 1725 K STREET, NW, SUITE 1000, WASHINGTON, DC, 20006, US

(73) Assignee: FUJITSU LIMITED, Kawasaki (JP)

(21) Appl. No.: 11/389,536

(22) Filed: Mar. 27, 2006

(30) Foreign Application Priority Data
Dec. 28, 2005 (JP) 2005-377474

(51) Int. Cl. H05K 1/11; H01R 12/04

(52) U.S. Cl. 174/262

(57) ABSTRACT

The present invention relates to a circuit board in which signal lines transmitting a signal are wired, and which is capable of increasing the speed of signal transmission. There is provided a circuit board in which signal lines are wired, including: a signal pad which is formed at the tip of the signal line and has a signal via in the center thereof; and plural ground vias which are formed in positions to surround the signal pad and transmit a ground potential over plural wiring layers.

### BACKGROUND OF THE INVENTION

1. Field of the Invention

The present invention relates to a circuit board in which signal lines transmitting a signal are wired.

2. Description of the Related Art

According to the tendency to increase the speed of circuit operation in recent years, a signal wiring pattern on a circuit board is also devised so as to enable the high-speed transmission of a signal to be performed.

Further, since there is a limit when only the signal wiring pattern is devised, a device of ground pad and the like is also proposed (see Japanese Patent Laid-Open No. 2001-24084, Japanese Patent Laid-Open No. 2000-100814).

However, there is an increasing need for even higher transmission speed, and hence, a device for realizing the even higher transmission speed is desired.

### SUMMARY OF THE INVENTION

The present invention has been made in view of the above circumstances and provides a circuit board which is improved in the signal transmission speed.

To this end, a circuit board according to the present invention in which signal lines are wired includes: a signal pad which is formed at the tip of the signal line and has in the center thereof a signal via to connect the signal lines with each other over plural wiring layers; and plural ground vias which are formed in positions to surround the signal pad and transmit a ground potential over the plural wiring layers.

In a printed circuit board for which the high-speed transmission performance is required, as represented by a LSI package board and the like, the performance is evaluated by using indexes referred to as S parameters. In order to improve the transmission performance, the signal quality with reduced loss is required. At present, the frequency band in which S11 representing the reflection characteristic satisfies the level from −100 dB up to −20 dB is about 5 GHz, but in order to effect the higher speed transmission, the frequency band needs to be expanded to at least 10 GHz or more. Conventionally, fine design values in relation to the signal transmission path have been specified in consideration of the high-speed transmission, but particular consideration has not been paid for the ground via. However, in order to realize the higher speed transmission, it is necessary to take into account the ground via, as well.

According to the present invention, a circuit board whose transmission characteristic is greatly improved is realized by arranging plural ground vias around a signal via.

Here, the circuit board according to the present invention, may have a ground pattern spreading to surround a signal pad with a predetermined clearance formed between the ground pattern and the signal pad, and have the ground vias formed in the ground pattern at positions adjacent to the clearance.

Further, in the circuit board according to the present invention, it is preferred that distances between the center of the signal via and each center of the plural ground vias formed in the positions to surround the signal pad, are equal to each other for the plural ground vias.

By arranging the signal via at the same distance from each of the plural ground vias, the simulation of performance and the pattern design are facilitated.

As described above, according to the present invention, it is possible to obtain a circuit board whose high-speed transmission characteristic of a signal is improved.

### BRIEF DESCRIPTION OF THE DRAWINGS

FIG. 1 is a perspective view of a circuit board in which signal lines are wired;

FIG. 2 is a partial cross-sectional view of the circuit board shown in FIG. 1;

FIG. 3 is a figure showing an example of a positional relationship between signal pads and ground pads;

FIG. 4 is a figure showing another example of a positional relationship between signal pads and ground pads;

FIG. 5 is a figure showing a positional relationship between signal pads and ground pads as a comparison example for the present invention;

FIG. 6 is a figure showing a simulation result of the frequency characteristic when a ground pad (a ground via) is arranged at a position adjacent to a signal pad;

FIG. 7 is a figure showing a simulation result of the frequency characteristic when a ground pad (a ground via) is arranged at a position adjacent to a signal pad;

FIG. 8 is a figure showing a simulation result of the frequency characteristic when two ground pads (two ground vias) are arranged at a position surrounding a signal pad, as shown in FIG. 3;

FIG. 9 is a figure showing a simulation result of the frequency characteristic when three ground pads (three ground vias) are arranged at a position surrounding a signal pad, as shown in FIG. 4; and

FIG. 10 is a figure showing another example of a positional relationship of signal pads and ground vias.

### DETAILED DESCRIPTION OF THE PREFERRED EMBODIMENTS

In the following, embodiments according to the present invention will be described.

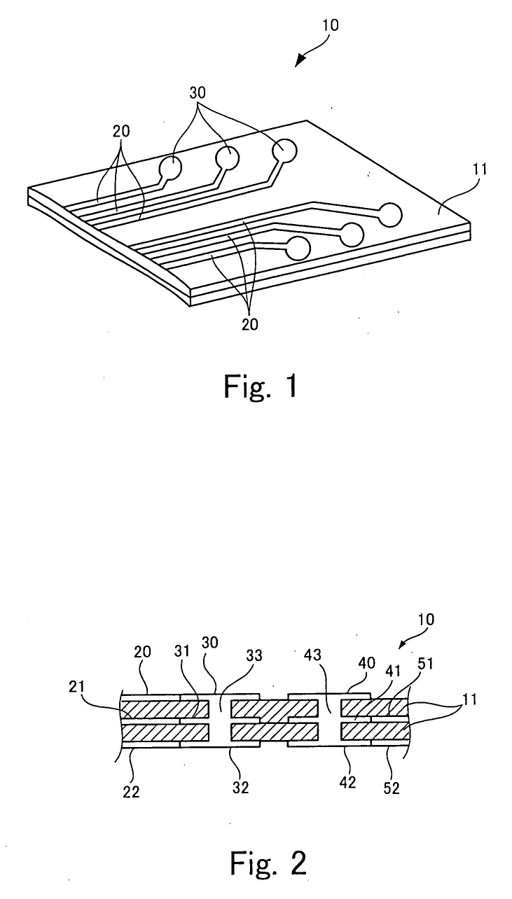

FIG. 1 is a perspective view showing a circuit board in which signal lines are wired.

On a board 11 of a circuit board 10, signal lines 20 for high-speed transmission of a signal are wired, and signal pads 30 are formed at the tip of each of the signal lines 20. In the circuit board 10 shown in FIG. 1, wirings and ground patterns are formed on the front surface, the rear surface and further on the intermediate layer of the board 11.

Note that the ground pattern is not shown in FIG. 1.

FIG. 2 is a partial cross-sectional view of the circuit board shown in FIG. 1.

On the front surface of the board 11 of the circuit board 10, a signal line 20 is wired and a signal pad 30 is formed at the tip of the signal line 20. Further, signal pads 31, 32 are also respectively formed on the intermediate layer and the rear surface of the board 11 at positions facing the signal pad 30. The signal pad 30 on the front surface of the board 11 and the signal pads 31, 32 on the intermediate layer and the rear surface of the board 11 are connected with each other via a signal via 33. The signal pad 31 on the intermediate layer of the board 11 is connected with a signal line 21 formed on the intermediate layer, and the signal pad 32 on the rear surface is connected with a signal line 22 formed on the rear surface.

Further, ground pads 40, 41, 42 are formed on the front surface, the intermediate layer, the rear surface at positions adjacent to the signal pads 30, 31, 32, respectively. The ground pads 40, 41, 42 are connected with each other via a ground via 43. Further, on the intermediate layer, a ground pattern 51 connected to the ground pad 41 is expanded, and on the rear surface, a ground pattern 52 connected to the ground pad 42 is expanded.

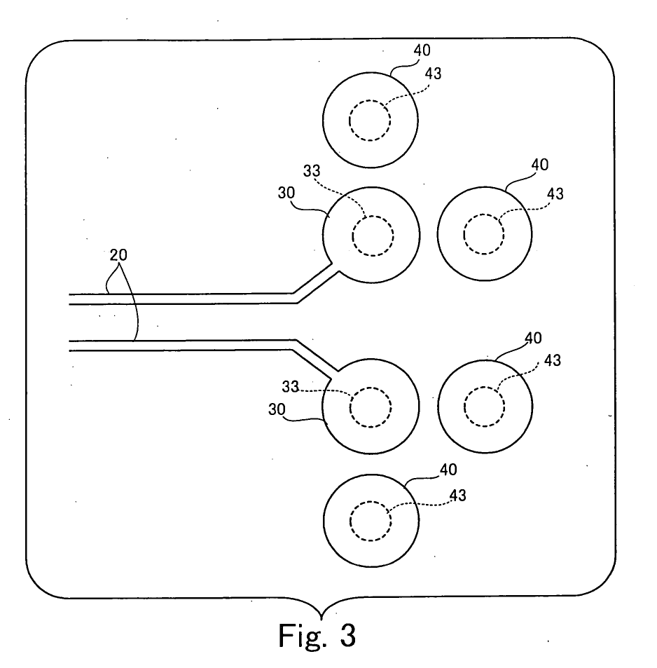

FIG. 3 is a figure showing an example of a positional relationship between the signal pads and the ground pads.

In FIG. 3, there are shown two signal lines 20 and signal pads 30 formed at the tip of each of the two signal lines 20. Signal vias 33 are formed at the center of each of the signal pads 30. The signal lines 20 are connected with the signal lines of other wiring layers (the intermediate layer and the rear surface) by the signal vias 33.

Further, in FIG. 3, two ground pads 40 are formed for each one of the signal pads 30 at positions to surround the each one of the signal pads 30. At the center of each of the two ground pads 40, a ground via 43 for effecting connection with the ground pattern of other wiring layers is formed.

In this way, by arranging the plural ground vias 43 (two in this case) at positions to surround the signal pad 30 having the signal via 33 at the center thereof, it is possible to significantly improve the high-speed signal transmission characteristic, as described later.

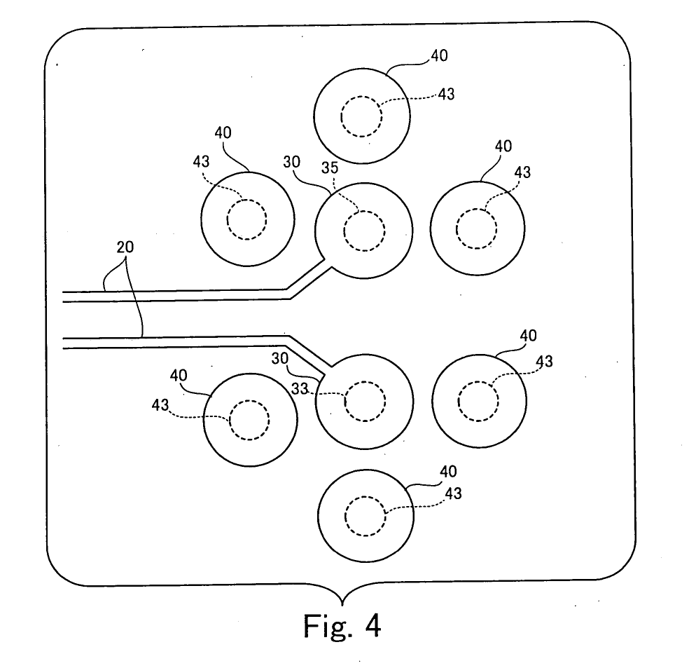

FIG. 4 is a figure showing another example of a positional relationship between the signal pads and the ground pads.

In contrast to FIG. 3, three ground pads 40, each having a ground via 43, are formed for each one of signal pads 30 with a signal via 33 formed at the center thereof, at positions to surround the each one of the signal pads 30.

In this way, by arranging the three ground pads 40, each having a ground via 43, at positions to surround the signal pad 30 having the signal via 33, the high-speed signal transmission characteristic can be further improved.

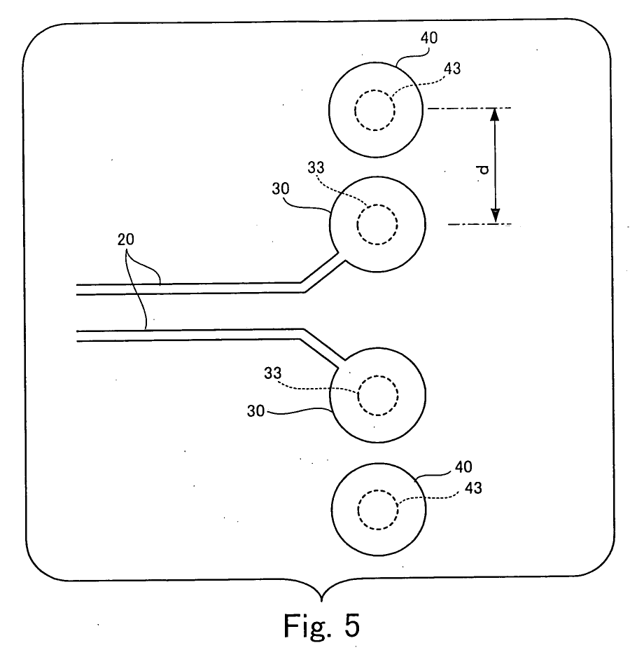

FIG. 5 is a figure showing a positional relationship between the signal pads and the ground pads as a comparison example for the present invention.

In the case of FIG. 5, for each one of signal pads 30, one ground pad 40 is formed at a position adjacent to the signal pad 30.

For purposes of the following explanation, a distance between the center of a signal via 33 formed at the center of the signal pad 30 and the center point of a ground via 43 formed at the center of the ground pad 40 formed at a position adjacent to the signal pad 30 is expressed by d. The distance “d” is applied not only to the case shown in FIG. 5, but also to the case where two or three ground pads 40 are formed so as to surround one signal pad 30, as shown in FIG. 3 and FIG. 4. Note that in the cases of FIG. 3 and FIG. 4, the distance “d” is the same for each of the plural ground pads arranged at positions to surround one of the signal pads 30.

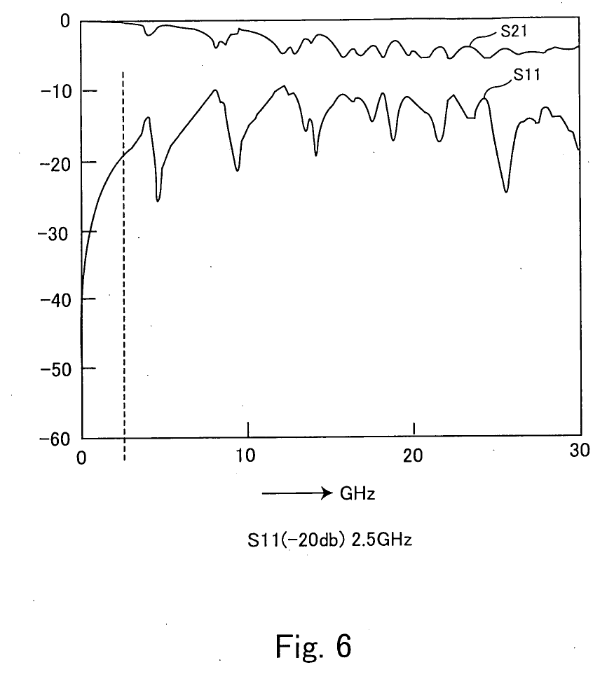

FIG. 6 is a figure showing a simulation result of the frequency characteristic when one ground pad (one ground via) is arranged at a position adjacent to one signal pad, as shown in FIG. 5. Further, FIG. 6 shows the case where the distance “d” (see FIG. 5) is set as d=1.6 mm.

Here, S21 of the S parameters is related to the transmittance of the signal, S11 is related to the reflectance of the signal, and the horizontal axis shows frequency (GHz). FIG. 6 means that the frequency characteristic is better when the transmittance (S21) is higher and the reflectance (S11) is lower.

In the case shown in FIG. 6, the level of the reflectance S11 of −20 dB or less is attained in the frequency range up to 2.5 GHz, and hence, the reflectance is desired to be lowered up to a frequency higher than this frequency.

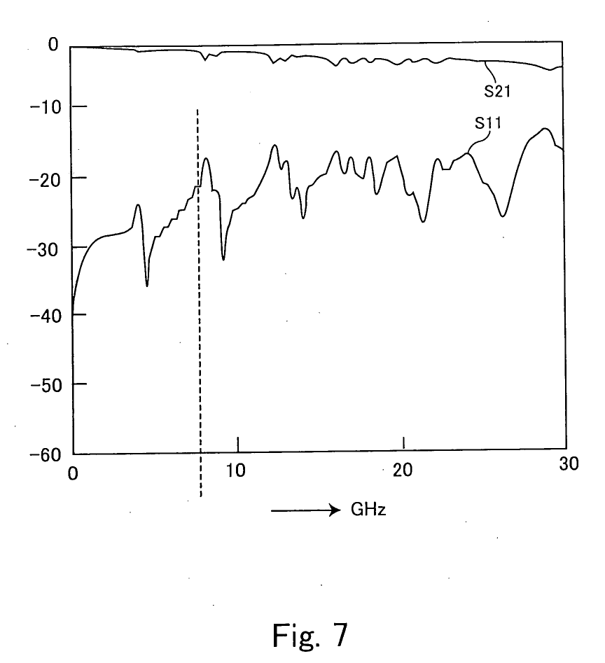

FIG. 7 is a figure showing a simulation result of the frequency characteristic when one ground pad (one ground via) is arranged at a position adjacent to one signal pad, as in the case shown in FIG. 6. However, unlike the case shown in FIG. 6, FIG. 7 shows the case where the distance “d” (see FIG. 5) is set as d=0.7 mm.

By bringing the ground via close to the signal via up to the distance “d”=0.7 mm, the level of the reflectance S11 of −20 dB or less is attained in the frequency range up to 8 GHz, and hence, the frequency characteristic is further improved as compared with the case shown in FIG. 6.

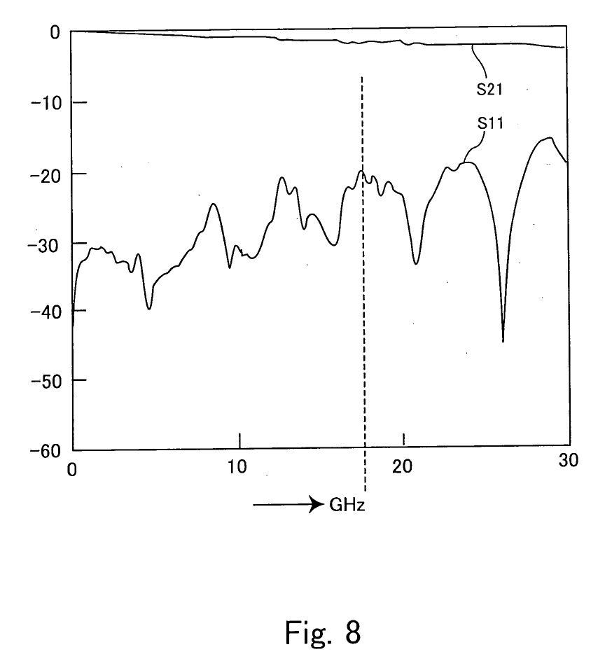

FIG. 8 is a figure showing a simulation result of the frequency characteristic when two ground pads (two ground vias) are arranged at a position to surround each one of the signal pads, as shown in FIG. 3. The distance “d” (see FIG. 5) is arranged to be the same for the two ground vias, and is set as d=0.7 mm as in the case shown in FIG. 7.

It is seen from FIG. 8 that the level of the reflectance S11 of −20 dB or less is maintained in the frequency range up to 17.6 GHz, and that the upper limit of the frequency range is extended to a frequency twice or higher than the frequency shown in FIG. 7.

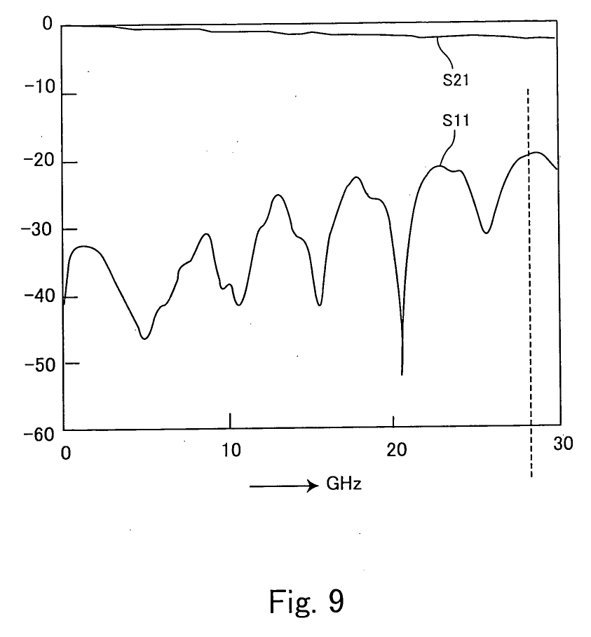

FIG. 9 is a figure showing a simulation result of the frequency characteristic when three ground pads (three ground vias) are arranged at a position surrounding each one of the signal pads, as shown in FIG. 4. The distance “d” (see FIG. 5) is arranged to be the same for the three ground vias, and is set as d=0.7 mm as in the case shown in FIG. 7 and FIG. 8.

It is seen from FIG. 9 that the level of the reflectance S11 of −20 dB or less is maintained in the frequency range up to 27.8 GHz, and that the frequency characteristic is further improved as compared even with the case shown in FIG. 8.

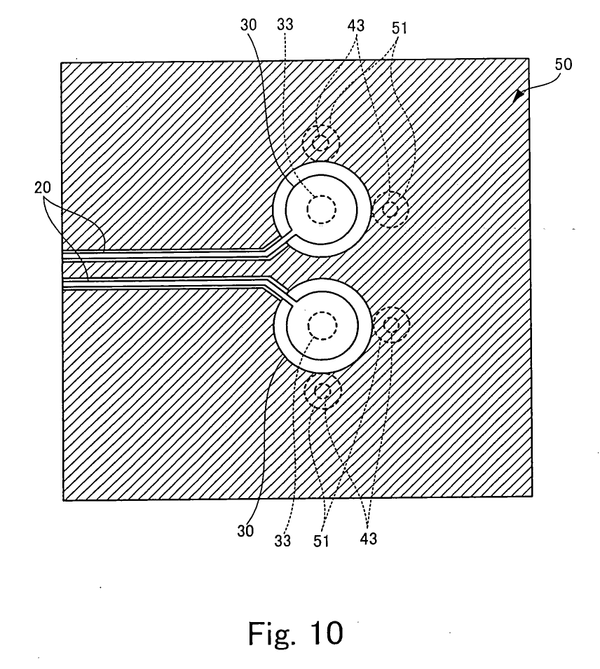

FIG. 10 is a figure showing another example of a positional relationship between signal pads and ground vias.

A signal pad 30 is formed at the tip of each signal line 20, and a signal via 33 (see FIG. 2) is formed at the center of each of the signal pads 30. Further, a ground pattern 50 is expanded around each of the signal lines 20 and the signal pads 30 with a predetermined clearance formed between the ground pattern 50 and the signal lines 20, and between the ground pattern 50 and the signal pads 30. In the position of the ground pattern adjacent to the clearance surrounding the signal pad 30, two ground vias 43 are formed for each one of the signal pads. These ground vias 43 connect the ground pattern 50 shown in FIG. 10 with a ground pad 51 formed in another layer, which is different from the layer shown in FIG. 10, in the circuit board 10 (see FIG. 1, FIG. 2).

Also in the case shown in FIG. 10, plural ground vias 43 (two in this case) are formed in positions to surround each one of the signal via 33, so that the high-speed transmission characteristic of a signal is significantly improved.

Note that examples in which two or three ground vias are arranged for one signal pad (one signal via) are shown here, but four or more ground vias may be arranged for one signal pad (one signal via).

What is claimed is:

1. A circuit board in which signal lines are wired, comprising:
a signal pad which is formed at the tip of each of the signal lines and has in the center thereof a signal via to connect the signal lines with each other over plural wiring layers; and
a ground via which is formed in a position adjacent to the signal pad and transmits a ground potential over the plural wiring layers.

2. The circuit board according to claim 1, further comprising plural ground vias which are formed in positions to surround the signal pad and transmit the ground potential over the plural wiring layers.

3. The circuit board according to claim 1, further comprising a ground pattern spreading to surround the signal pad with a predetermined clearance formed between the ground pattern and the signal pad, wherein the ground via is formed in the ground pattern in a position adjacent to the clearance.

4. The circuit board according to claim 2, further comprising a ground pattern spreading to surround the signal pad with a predetermined clearance formed between the ground pattern and the signal pad, wherein the ground via is formed in the ground pattern in a position adjacent to the clearance.

5. The circuit board according to claim 2, wherein distances between the center of the signal via and each center of the plural ground vias formed in positions to surround the signal pad are equal to each other for the plural ground vias.
